(19) United States
(12) Patent Application Publication
(10) Pub. No.: US 2026/0020258 A1
(43) Pub. Date: Jan. 15, 2026

(54) SEMICONDUCTOR CAPACITOR AND METHOD OF FORMING THE SAME

(71) Applicant: NANYA TECHNOLOGY CORPORATION, New Taipei City (TW)

(72) Inventor: Kai Hung LIN, New Taipei City (TW)

(21) Appl. No.: 18/766,663

(22) Filed: Jul. 9, 2024

(51) Int. Cl. H01L 21/02; H01L 21/3213

(52) U.S. Cl. CPC H10D 1/042; H10D 1/694; H10D 1/714; H10P 14/6339; H10P 14/69392; H10P 50/267

(57) ABSTRACT

The present disclosure provides a semiconductor capacitor. The semiconductor capacitor includes a first conductive layer, a second conductive layer and a dielectric layer. The dielectric layer is located between the first conductive layer and the second conductive layer, and the first conductive layer and/or the second conductive layer are performed a plasma treatment to remove impurities therein and replace the impurities with nitrogen atoms. In addition, a method of forming a semiconductor capacitor is also disclosed.

### BACKGROUND

### Field of Invention

The present disclosure relates to a capacitor and a method of forming the same. More particularly, the present disclosure relates to a semiconductor capacitor and a method of forming the same.

### Description of Related Art

In recent decades, demand to storage capability has increased as electronic products continue to improve. In order to increase storage capability of a memory device (e.g., a DRAM device), more memory cells are integrated in the memory device. As the integration level increases, the fabrication process of the memory device may become much more complicated, and the process window may become rather narrow.

As electronic devices become lighter and thinner, semiconductor devices, such as dynamic random access memory (DRAM) become more highly integrated. Further, the performance of the DRAM is improved via shortening the pitch between the semiconductor structures in the DRAM. Due to shrinking the size of the semiconductor structure, in addition to increasing the difficulty of the manufacturing process, the components in the semiconductor structures are also prone to leakage resulting from too close distances.

As a result, in the semiconductor manufacturing process, how to manufacture a semiconductor capacitor that has high capacitance and reduced current leakage has become an important issue.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments / key elements of the present invention or define the scope of the invention.

One objective of the embodiments of the present invention is to provide a semiconductor capacitor and a method of forming the same able to improve the leakage current and the resistance thereof.

To achieve these and other advantages and in accordance with the objective of the embodiments of the present invention, as the embodiment broadly describes herein, the embodiments of the present disclosure provides a semiconductor capacitor including a first conductive layer, a second conductive layer and a dielectric layer. The dielectric layer is formed between the first conductive layer and the second conductive layer. In addition, the first conductive layer or the second conductive layer is performed by a plasma treatment to remove impurities therein and replace the impurities with nitrogen atoms.

In some embodiments, the first conductive layer is a bottom cell plate and the second conductive layer is a top cell plate.

In some embodiments, the bottom cell plate and the top cell plate comprise a titanium nitride film, a titanium silicon nitride film, a platinum film, a gold film, or combinations thereof.

In some embodiments, a thickness of the bottom cell plate is about 10 angstroms to 100 angstroms and a thickness of the top cell plate is about 10 angstroms to 100 angstroms.

In some embodiments, the dielectric layer includes atomic layer deposition (ALD) films made of hafnium dioxide, zirconium dioxide, aluminum oxide, or combinations thereof.

In some embodiments, the dielectric layer includes a first metal oxide film, a second metal oxide film and a third metal oxide film. The first metal oxide film contacts the first conductive layer, the third metal oxide film contacts the second conductive layer, and the second metal oxide film is formed between the first metal oxide film and the third metal oxide film, wherein the first metal oxide film and the third metal oxide film are hafnium dioxide films and a thickness of the dielectric layer is about 3 nm to 10 nm.

In some embodiments, a total thickness of hafnium dioxide films of the dielectric layer is less than or equal to 2.5 nm.

In some embodiments, the second conductive layer includes an outer second conductive layer formed outside the first conductive layer and an inner second conductive layer. The outer second conductive layer is formed outside the first conductive layer and the inner second conductive layer is formed inside the first conductive layer.

In some embodiments, the dielectric layer includes an outer dielectric layer and an inner dielectric layer. The outer dielectric layer is formed between the outer second conductive layer and the first conductive layer, and the inner dielectric layer is formed between the inner second conductive layer and the first conductive layer.

In some embodiments, the outer dielectric layer, the inner dielectric layer, the outer second conductive layer, the inner second conductive layer and the first conductive layer are hollow cylinders.

According to another aspect of the present disclosure, a method of forming a semiconductor capacitor including the steps of providing a first conductive layer, forming a dielectric layer on the first conductive layer, and forming a second conductive layer on the dielectric layer. In addition, the first conductive layer or the second conductive layer is performed by a plasma treatment to remove impurities and replace the impurities with nitrogen atoms.

In some embodiments, the first conductive layer is a bottom cell plate and the second conductive layer is a top cell plate.

In some embodiments, the bottom cell plate and the top cell plate include a titanium nitride film, a titanium silicon nitride film, a platinum film, a gold film, or combinations thereof.

In some embodiments, a thickness of the bottom cell plate is about 10 angstroms to 100 angstroms and a thickness of the top cell plate is about 10 angstroms to 100 angstroms.

In some embodiments, the step of forming a dielectric layer includes performing an atomic layer deposition (ALD) process to form hafnium dioxide, zirconium dioxide, aluminum oxide films, or combinations thereof.

In some embodiments, the step of forming a dielectric layer includes forming a first metal oxide film, forming a second metal oxide film and forming a third metal oxide film. In addition, the first metal oxide film contacts the first conductive layer, the third metal oxide film contacts the second conductive layer, and the second metal oxide film is formed between the first metal oxide film and the third metal oxide film. Furthermore, the first metal oxide film and the third metal oxide film are hafnium dioxide films and a thickness of the dielectric layer is 3 nm to 10 nm.

In some embodiments, a total thickness of hafnium dioxide films of the dielectric layer is less than or equal to 2.5 nm.

In some embodiments, the step of forming the dielectric layer includes forming an outer dielectric layer and an inner dielectric layer on the second conductive layer. In addition, the outer dielectric layer is located outside the second conductive layer and the inner dielectric layer is located inside the second conductive layer.

In some embodiments, the step of forming the second conductive layer includes forming an outer second conductive layer and an inner second conductive layer. In addition, the outer second conductive layer is located outside the outer dielectric layer, and the inner second conductive layer is located inside the inner dielectric layer.

In some embodiments, reaction gases for the plasma treatment includes hydrogen, nitrogen and argon, and a ratio is 1-2 : 1-2 : 0.5-1.

Hence, the semiconductor capacitor and the method of forming the same disclosed in the present disclosure may remove chlorine atoms in the conductive layer through the plasma treatment and replace the chlorine atoms with nitrogen atoms to reduce leakage current and resistivity. The hafnium oxide formed at both end surfaces of the stacked dielectric layer may further reduce leakage current and resistivity so as to effectively improve the yield and quality of the semiconductor capacitors.

It is to be understood that both the foregoing general description and the following detailed description are by examples, and are intended to provide further explanation of the disclosure as claimed.

The features, aspects, and advantages of the present disclosure are better understood by referring to the following detailed description. It is noted that both the foregoing general description and the following detailed description are merely illustrative and are intended to provide further explanations of the appended claims.

### BRIEF DESCRIPTION OF THE DRAWINGS

The present disclosure is best understood from the following detailed description and the accompanying figures. It is noted that the elements in the figures may not be drawn to meet the exact scale. Some elements may be drawn with increased or decreased sizes for clarity of the discussion.

FIG. 1 is a flow chart of a method of forming a semiconductor capacitor according to some embodiments of the present disclosure.

FIGS. 2A, 3A and 4A are top-view schematics of a semiconductor capacitor in the intermediate stages of a method of forming a semiconductor capacitor according to a first embodiment of the present disclosure.

FIGS. 2B, 3B and 4B are cross-section-view schematics of a semiconductor capacitor in the intermediate stages of a method of forming a semiconductor capacitor according to a first embodiment of the present disclosure.

FIGS. 5A, 6A, 7A and 8A are top-view schematics of a semiconductor capacitor in the intermediate stages of a method of forming a semiconductor capacitor according to a second embodiment of the present disclosure.

FIGS. 5B, 6B, 7B and 8B are cross-section-view schematics of a semiconductor capacitor in the intermediate stages of a method of forming a semiconductor capacitor according to a second embodiment of the present disclosure.

FIG. 9 is a partial sectional view of a semiconductor capacitor according to some embodiments of the present disclosure.

### DETAILED DESCRIPTION

To make the description of the present disclosure more detailed and complete, explanatory descriptions of the aspects and specific implementations of the embodiments are provided below. It is not to limit the embodiments of the present disclosure to only one form. The embodiments of the present disclosure can combine or be substituted with each other under beneficial circumstances. Other embodiments may be appended without further description or explanation.

Furthermore, spatially relative terms, such as below and above, etc., may be used in the present disclosure to describe the relationship of one element or feature to another element or feature in the drawings. In addition to the orientation depicted in the figures, spatially relative terms are intended to encompass different orientations of the device in use or step. For example, the device may be otherwise oriented (eg, rotated 90 degrees or otherwise) and the spatially relative terms of this disclosure are to be interpreted accordingly. In this disclosure, unless otherwise indicated, the same element numbers in different figures refer to the same or similar elements formed from the same or similar materials by the same or similar methods.

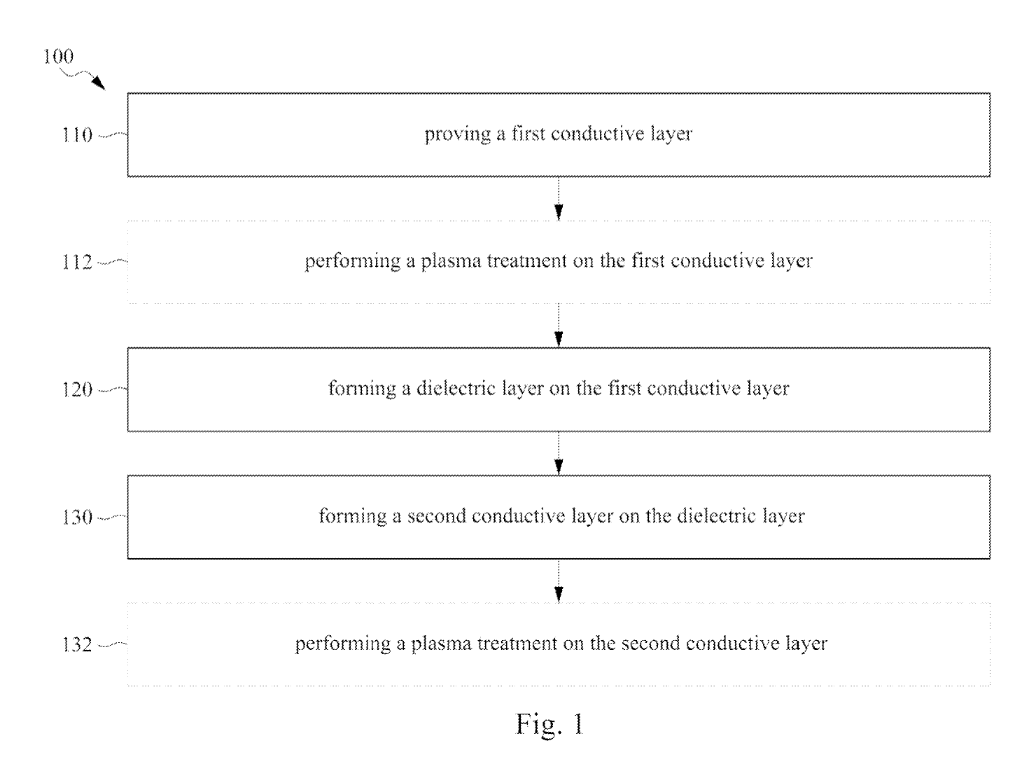

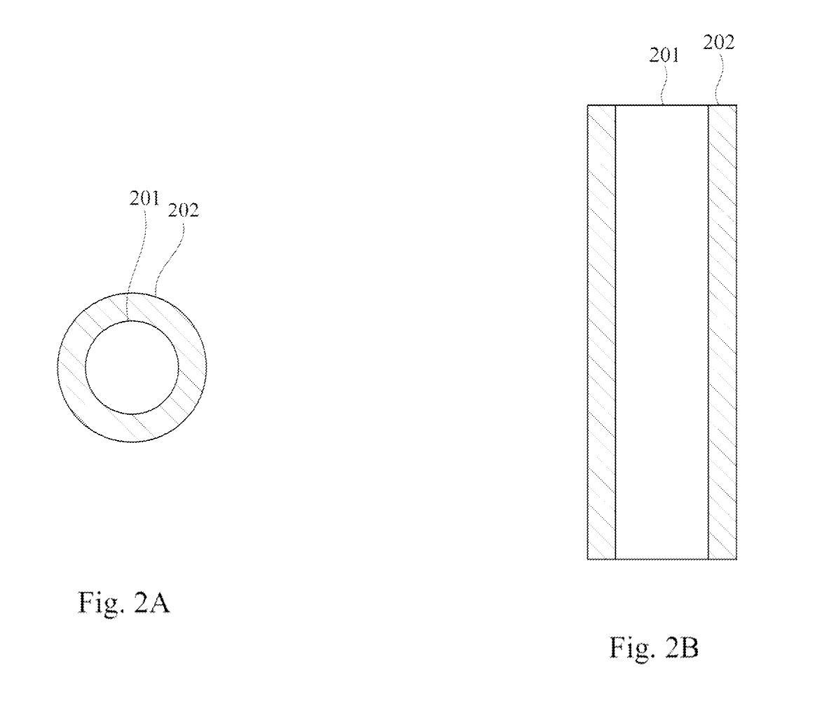

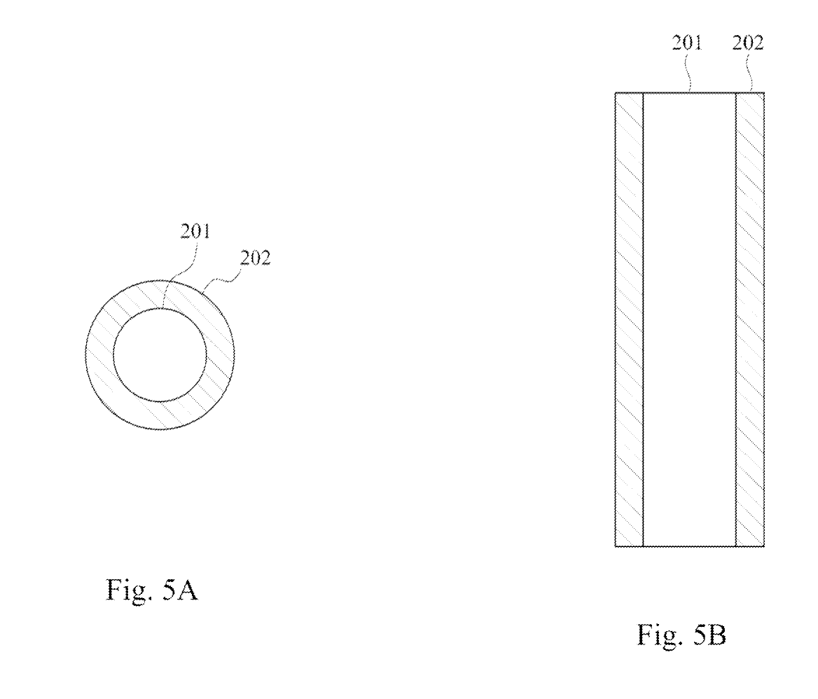

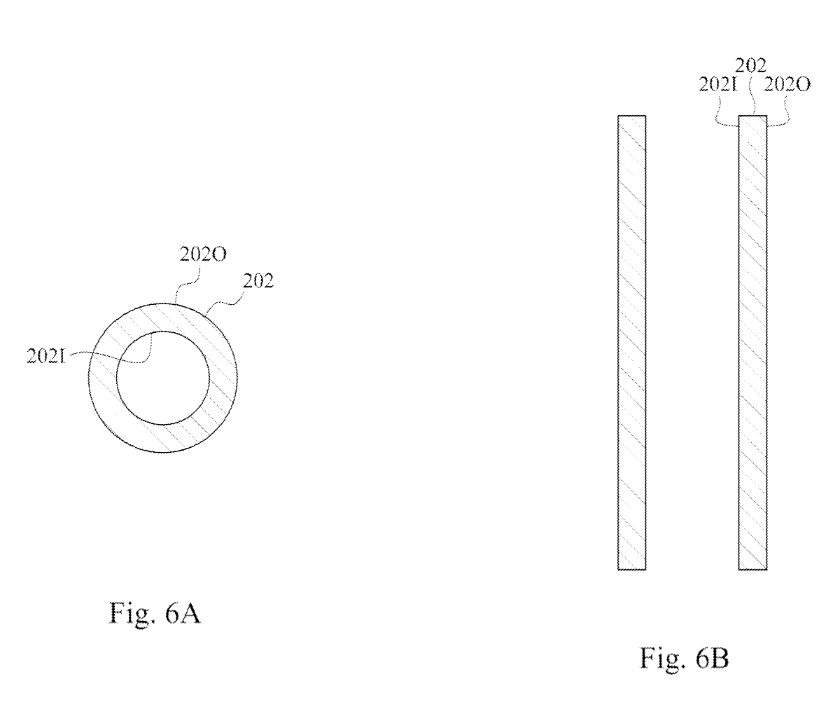

FIG. 1 is a flow chart of the method 100 described above according to some embodiments of the present disclosure. FIGS. 2A, 3A, and 4A in a top view, and FIGS. 2B, 3B, and 4B in a cross-section view are schematics of the semiconductor capacitor in the intermediate stages of the method 100 according to a first embodiment of the present disclosure. Please read FIGS. 2A to 4B when reading FIG. 1. FIGS. 5A, 6A, 7A, and 8A in a top view, and FIGS. 5B, 6B, 7B, and 8B in a cross-section view are schematics of the semiconductor capacitor in the intermediate stages of the method 100 according to a second embodiment of the present disclosure. The difference between the first embodiment and the second embodiment is explained below. Please read FIGS. 5A to 8B when reading FIG. 1.

In FIG. 1, a step 110 includes providing a first conductive layer 202. A step 120 includes forming a dielectric layer 203, e.g. a metal oxide insulating layer, on the first conductive layer 202. Please refer to FIGS. 2A and 2B to FIGS. 3A and 3B, and FIGS. 5A and 5B to FIGS. 7A and 7B. In some embodiments, before the step 110, the first conductive layer 202 can form on any substrate, such as a cylindrical substrate 201 discussed later, and the substrate can be any shape, such as a planar plate or a cylinder. The materials of the dielectric layer 203 deposit on the first conductive layer 202 to form the dielectric layer 203. The dielectric layer 203 is formed on the first conductive layer 202. In some embodiments, the first conductive layer 202 includes a titanium nitride film, a titanium silicon nitride film, a platinum film, a gold film, or combinations thereof. In some embodiments, the dielectric layer 203 includes hafnium dioxide, zirconium dioxide, aluminum oxide, or combinations thereof. In some embodiments, forming the dielectric layer 203 includes performing an atomic layer deposition (ALD) process to form the hafnium dioxide film, zirconium dioxide film, aluminum oxide film, or combinations thereof, but not limited thereto.

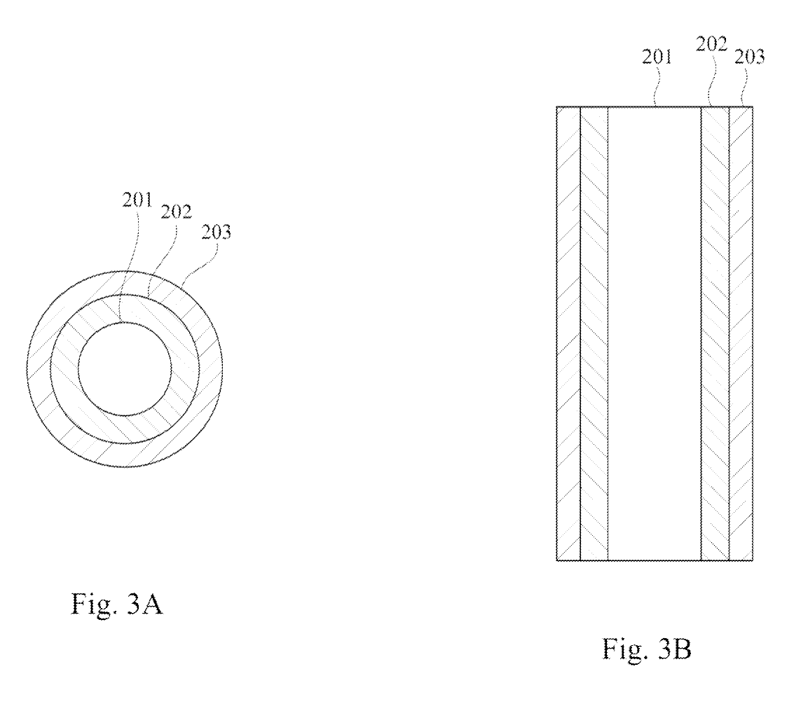

In some embodiments, the method 100 further includes forming the first conductive layer 202 on a cylindrical substrate 201, such as the first embodiment shown in FIGS. 2A and 2B to FIGS. 3A and 3B. When the first conductive layer 202 is formed on the cylindrical substrate 201, a shape of the first conductive layer 202 is a hollow cylinder, making the dielectric layer 203 formed on the first conductive layer 202 also a hollow cylinder. The shape of the hollow cylinder will favor the crystallization of the dielectric layer. In some embodiments, the cylindrical substrate 201 includes silicon or silicon dioxide.

In some embodiments, the method 100 further includes forming the first conductive layer 202 on a cylindrical substrate 201, and etching the cylindrical substrate 201 to form the first conductive layer 202 in a shape of a hollow cylinder, such as the second embodiment shown in FIGS. 5A and 5B to FIGS. 7A and 7B. Because the first conductive layer 202 is formed on the cylindrical substrate 201, a shape of the first conductive layer 202 is a hollow cylinder. After etching the cylindrical substrate 201 wrapped inside the first conductive layer 202, an inner surface 202I and an outer surface 202O of the first conductive layer 202 are exposed. Therefore, forming the dielectric layer 203 in the step 120 includes forming an outer dielectric layer 203A on the outer surface 202O of the first conductive layer 202, and forming an inner dielectric layer 203B on the inner surface 202I of the first conductive layer 202. The dielectric layer 203 in the second embodiment includes the outer dielectric layer 203A and the inner dielectric layer 203B, and both the outer dielectric layer 203A and the inner dielectric layer 203B are in a shape of a hollow cylinder and metal oxide insulating layers. In addition, because the semiconductor capacitor of the second embodiment includes two separated dielectric portions, i.e., the outer dielectric layer 203A and the inner dielectric layer 203B, to store charges, the capacitance of the semiconductor capacitor in the second embodiment is generally larger than the capacitance of the semiconductor capacitor in the first embodiment. In some embodiments, the cylindrical substrate 201 includes silicon or silicon dioxide. In some embodiments, the outer dielectric layer 203A includes hafnium dioxide, zirconium dioxide, aluminum oxide, or combinations thereof, for example, stacked metal oxide films, e.g., hafnium dioxide, zirconium dioxide, aluminum oxide films, but not limited thereto. In addition, the inner dielectric layer 203B includes hafnium dioxide, zirconium dioxide, aluminum oxide, or combinations thereof, for example, stacked metal oxide films, e.g., hafnium dioxide, zirconium dioxide, aluminum oxide films, but not limited thereto.

In some embodiments, etching the cylindrical substrate 201 includes any acceptable semiconductor processes.

In some embodiments, forming the outer dielectric layer 203A includes performing an atomic layer deposition (ALD) process, and forming the inner dielectric layer 203B includes performing an atomic layer deposition (ALD) process.

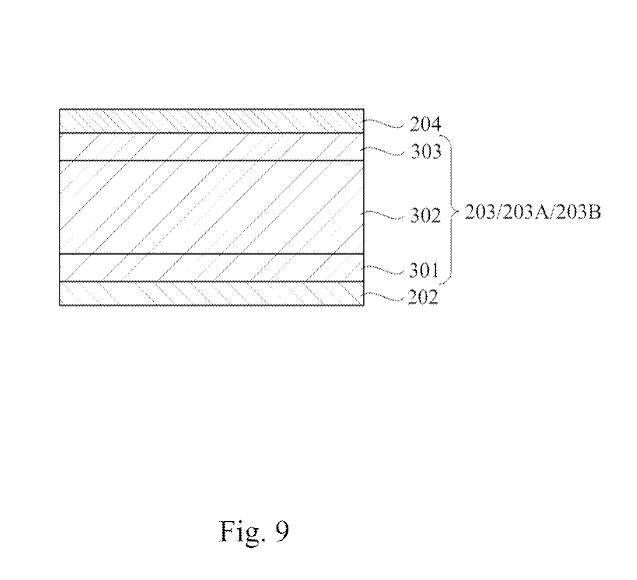

Referring to FIG. 9, as shown, it is worth noting that the metal oxide films, contacting the first conductive layer 202 and the second conductive layer 204, of the dielectric layer 203, the outer dielectric layer 203A and/or the inner dielectric layer 203B are preferably hafnium dioxide films rather than aluminum oxide films. In some embodiments, the first metal oxide film 301 and the third metal oxide film 303 are preferably hafnium dioxide films. In addition, the second metal oxide film 302 may be stacked films of hafnium dioxide, zirconium dioxide and/or aluminum oxide, but not limited thereto.

In FIG. 1, a step 130 includes forming a second conductive layer 204 on the dielectric layer 203. Please refer to FIGS. 3A and 3B to FIGS. 4A and 4B, and FIGS. 7A and 7B to FIGS. 8A and 8B. The materials of the second conductive layer 204 deposit on the dielectric layer 203 and react to form the second conductive layer 204. In some embodiments, the second conductive layer 204 includes a titanium nitride film, a titanium silicon nitride film, a platinum film, a gold film, or combinations thereof. In some embodiments, forming the second conductive layer 204 includes performing an atomic layer deposition (ALD) process.

In some embodiments, the first conductive layer 202 is a bottom cell plate of a semiconductor capacitor and the second conductive layer 204 is a top cell plate of the semiconductor capacitor.

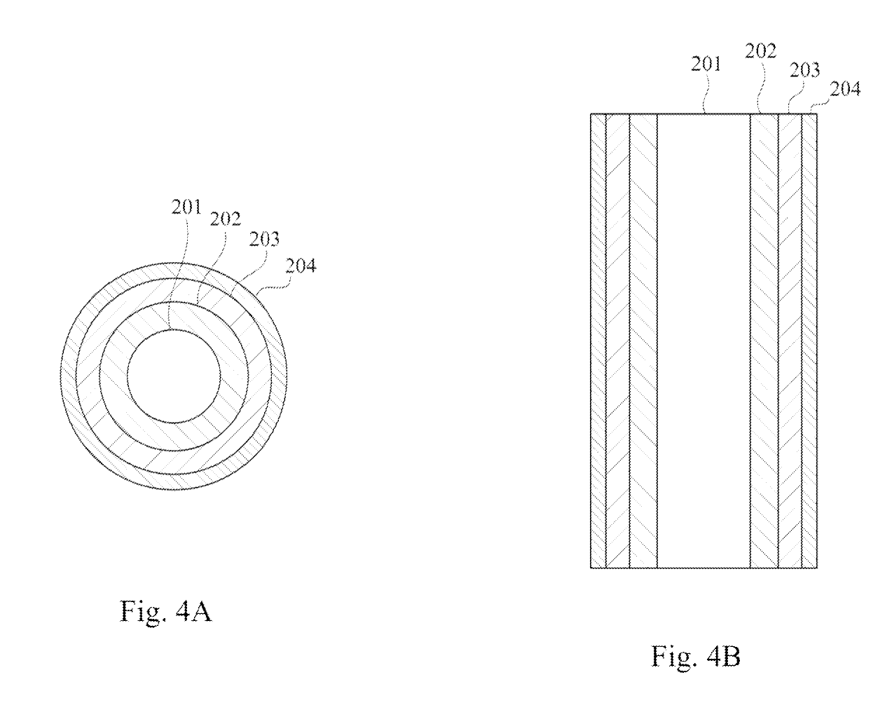

In the first embodiment shown in FIGS. 3A and 3B to FIGS. 4A and 4B, the second conductive layer 204 formed on the hollow cylinder of the dielectric layer 203 is also a hollow cylinder.

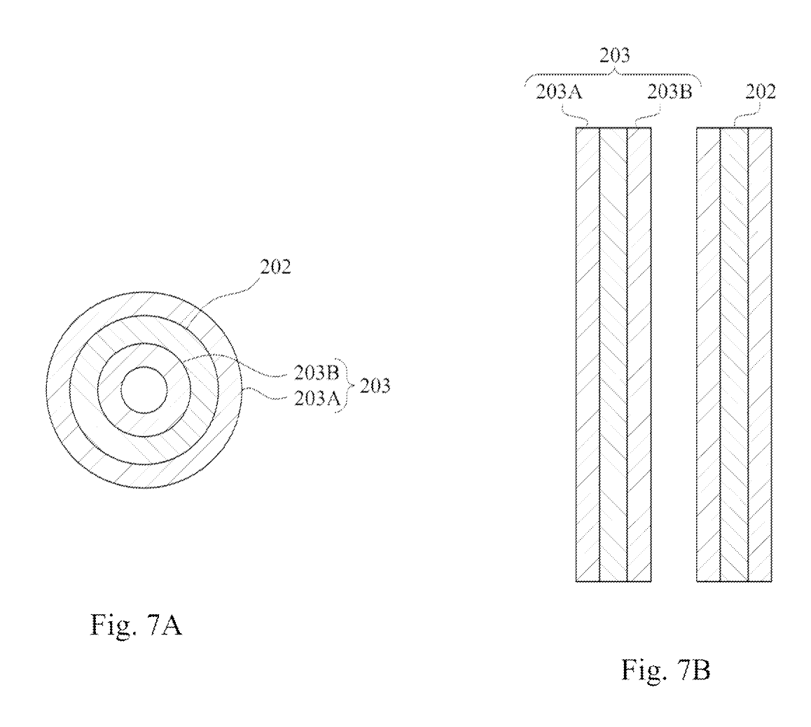

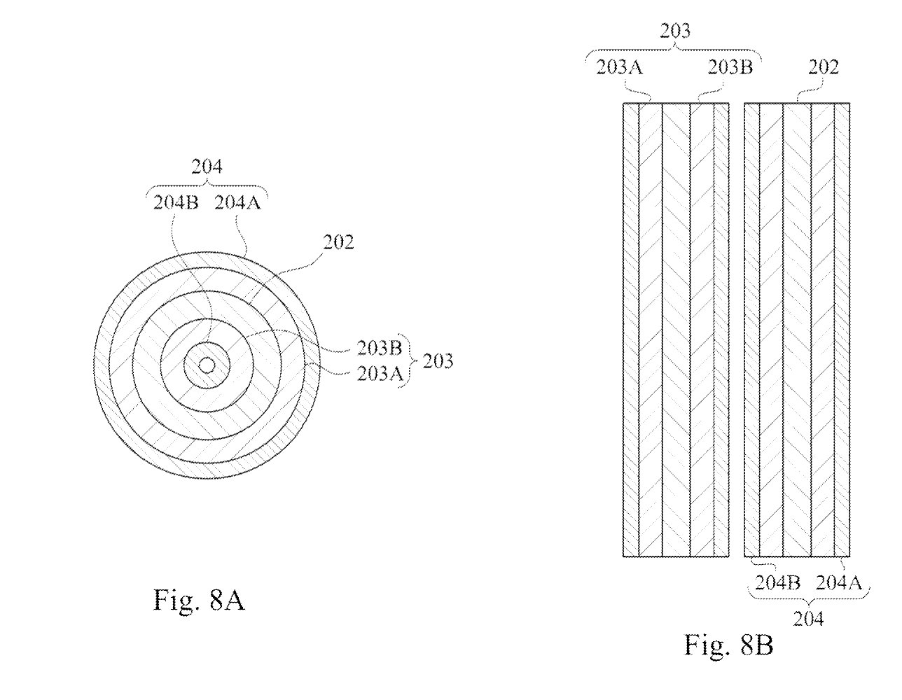

In the second embodiment shown in FIGS. 7A and 7B to FIGS. 8A and 8B, the step 130 of forming the second conductive layer 204 includes forming an outer second conductive layer 204A on the outer dielectric layer 203A, and forming an inner second conductive layer 204B on the inner dielectric layer 203B. In other words, the second conductive layer 204 in the second embodiment includes the outer second conductive layer 204A and the inner second conductive layer 204B, in which the outer second conductive layer 204A formed on the hollow cylinder of the outer dielectric layer 203A is also a hollow cylinder, and the inner second conductive layer 204B formed on the hollow cylinder of the inner dielectric layer 203B is also a hollow cylinder. In addition, the hollow cylinder of the first conductive layer 202 and the hollow cylinders of the outer second conductive layer 204A and the inner second conductive layer 204B sandwich the outer dielectric layer 203A and the inner dielectric layer 203B therebetween. In some embodiments, the outer second conductive layer 204A includes a titanium nitride film, a titanium silicon nitride film, a platinum film, a gold film, or combinations thereof, and the inner second conductive layer 204B includes a titanium nitride film, a titanium silicon nitride film, a platinum film, a gold film, or combinations thereof. In some embodiments, forming the outer second conductive layer 204A includes performing an atomic layer deposition (ALD) process, and forming the inner second conductive layer 204B includes performing an atomic layer deposition (ALD) process.

Referring to FIG. 1, a step 112 and a step 132 are illustrated with dotted line frames. After the first conductive layer 202 and/or the second conductive layer 204 are formed, a plasma treatment may be used to remove the impurities in the first conductive layer 202 and/or the second conductive layer 204, for example, chlorine atoms, and the chlorine atoms are replaced with nitrogen atoms. In addition, the plasma treatment may be performed after the first conductive layer 202 is formed, or after the second conductive layer 204 is formed, or the plasma treatment may be performed after both the first conductive layer 202 and the second conductive layer 204 are formed.

In some embodiments, the first conductive layer 202 and the second conductive layer 204 are respectively a bottom cell plate and a top cell plate. In some embodiments, the thickness of the bottom cell plate and the top cell plate is about 10 Å (angstrom) to 100 Å.

In some embodiments, a total thickness of the hafnium dioxide films in the dielectric layer 203 is less than or equal to 2.5 nm (nanometer).

In addition, in some embodiments, reaction gases for the plasma treatment includes hydrogen, nitrogen and argon, and a ratio of the hydrogen, nitrogen and argon is about 1-2 : 1-2 : 0.5-1.

Accordingly, the semiconductor capacitor and the method of forming the same disclosed in the present disclosure may remove chlorine atoms in the conductive layer through the plasma treatment and replace the chlorine atoms with nitrogen atoms to reduce leakage current and resistivity. The hafnium oxide formed at both end surfaces of the stacked dielectric layer may further reduce leakage current and resistivity so as to effectively improve the yield and quality of the semiconductor capacitors.

The present disclosure is described in considerable detail with some embodiments. Other embodiments may be feasible. Therefore, the scope and spirit of the claims that are appended should not be limited to the description of the embodiments in the present disclosure.

For one skilled in the art, the present disclosure may be modified and changed as long as not departing from the spirit and scope of the present disclosure. If the modifications and changes are within the scope and spirit of the claims that are appended, they are covered by the present disclosure.

What is claimed is:

1. A semiconductor capacitor, comprising:
a first conductive layer;
a second conductive layer; and
a dielectric layer formed between the first conductive layer and the second conductive layer, wherein the first conductive layer or the second conductive layer is performed by a plasma treatment to remove impurities and replace the impurities with nitrogen atoms.

2. The semiconductor capacitor according to claim 1, wherein the first conductive layer is a bottom cell plate and the second conductive layer is a top cell plate.

3. The semiconductor capacitor according to claim 2, wherein the bottom cell plate and the top cell plate comprise a titanium nitride film, a titanium silicon nitride film, a platinum film, a gold film, or combinations thereof.

4. The semiconductor capacitor according to claim 3, wherein a thickness of the bottom cell plate is about 10 angstroms to 100 angstroms and a thickness of the top cell plate is about 10 angstroms to 100 angstroms.

5. The semiconductor capacitor according to claim 1, wherein the dielectric layer comprises atomic layer deposition (ALD) films made of hafnium dioxide, zirconium dioxide, aluminum oxide, or combinations thereof.

6. The semiconductor capacitor according to claim 5, wherein the dielectric layer comprises:
a first metal oxide film;
a second metal oxide film; and
a third metal oxide film, wherein the first metal oxide film contacts the first conductive layer, the third metal oxide film contacts the second conductive layer, and the second metal oxide film is formed between the first metal oxide film and the third metal oxide film, wherein the first metal oxide film and the third metal oxide film are hafnium dioxide films and a thickness of the dielectric layer is 3 nm to 10 nm.

7. The semiconductor capacitor according to claim 5, wherein a total thickness of hafnium dioxide films of the dielectric layer is less than or equal to 2.5 nm.

8. The semiconductor capacitor according to claim 5, wherein the second conductive layer comprises:
an outer second conductive layer formed outside the first conductive layer; and
an inner second conductive layer formed inside the first conductive layer.

9. The semiconductor capacitor according to claim 8, wherein the dielectric layer comprises:
an outer dielectric layer formed between the outer second conductive layer and the first conductive layer; and
an inner dielectric layer formed between the inner second conductive layer and the first conductive layer.

10. The semiconductor capacitor according to claim 9, wherein the outer dielectric layer, the inner dielectric layer, the outer second conductive layer, the inner second conductive layer and the first conductive layer are hollow cylinders.

11. A method of forming a semiconductor capacitor, comprising:
providing a first conductive layer;
forming a dielectric layer on the first conductive layer; and
forming a second conductive layer on the dielectric layer, wherein the first conductive layer or the second conductive layer is performed by a plasma treatment to remove impurities and replace the impurities with nitrogen atoms.

12. The method of forming a semiconductor capacitor according to claim 11, wherein the first conductive layer is a bottom cell plate and the second conductive layer is a top cell plate.

13. The method of forming a semiconductor capacitor according to claim 12, wherein the bottom cell plate and the top cell plate comprise a titanium nitride film, a titanium silicon nitride film, a platinum film, a gold film, or combinations thereof.

14. The method of forming a semiconductor capacitor according to claim 13, wherein a thickness of the bottom cell plate is about 10 angstroms to 100 angstroms and a thickness of the top cell plate is about 10 angstroms to 100 angstroms.

15. The method of forming a semiconductor capacitor according to claim 11, wherein a step of forming a dielectric layer comprises:
performing an atomic layer deposition (ALD) process to form hafnium dioxide, zirconium dioxide, aluminum oxide films, or combinations thereof.

16. The method of forming a semiconductor capacitor according to claim 15, wherein the step of forming a dielectric layer comprises:
forming a first metal oxide film;
forming a second metal oxide film; and
forming a third metal oxide film, wherein the first metal oxide film contacts the first conductive layer, the third metal oxide film contacts the second conductive layer, and the second metal oxide film is formed between the first metal oxide film and the third metal oxide film, wherein the first metal oxide film and the third metal oxide film are hafnium dioxide films and a thickness of the dielectric layer is 3 nm to 10 nm.

17. The method of forming a semiconductor capacitor according to claim 15, wherein a total thickness of hafnium dioxide films of the dielectric layer is less than or equal to 2.5 nm.

18. The method of forming a semiconductor capacitor according to claim 11, wherein the step of forming the dielectric layer comprises:
forming an outer dielectric layer and an inner dielectric layer on the second conductive layer, wherein the outer dielectric layer is located outside the second conductive layer and the inner dielectric layer is located inside the second conductive layer.

19. The method of forming a semiconductor capacitor according to claim 18, wherein a step of forming the second conductive layer comprises:
forming an outer second conductive layer and an inner second conductive layer, wherein the outer second conductive layer is located outside the outer dielectric layer and the inner second conductive layer is located inside the inner dielectric layer.

20. The method of forming a semiconductor capacitor according to claim 11, wherein reaction gases for the plasma treatment comprises hydrogen, nitrogen and argon, and a ratio is 1-2 : 1-2 : 0.5-1.
